(19) United States
(12) Patent Application Publication
(10) Pub. No.: US 2010/0186811 A1
(43) Pub. Date: Jul. 29, 2010

(54) Silicon Carbonitride Antireflective Coating

(75) Inventors: Dong Seop Kim, Gyeonggi-do (KR); Moon Hee Kang, Atlanta, GA (US); Ajeet Rohatgi, Marietta, GA (US); Michael Davies, Ottawa (CA); Junegie Hong, Beaconsfield (CA); Genowefa Jakubowska-Okoniewski, Pierrefonds (CA); Abasifreke Udo Ebong, Marietta, GA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sixtron Advanced Materials, Inc., Dorval (CA)

(21) Appl. No.: 12/547,435

(22) Filed: Aug. 25, 2009

Related U.S. Application Data
(63) Continuation-in-part of application No. 12/325,028, filed on Nov. 28, 2008.
(60) Provisional application No. 61/136,292, filed on Aug. 26, 2008.

(51) Int. Cl. H01L 31/0216; H01L 31/18

(52) U.S. Cl. 136/256; 438/72; 257/E31.119

(57) ABSTRACT

An antireflective coating for silicon-based solar cells comprising amorphous silicon carbonitride, wherein the amount of carbon in the silicon carbonitride is from 5 to 25%, a solar cell comprising the antireflective coating, and a method of preparing the antireflective coating.

### CROSS-REFERENCE TO RELATED APPLICATIONS

This application claims the benefit of U.S. Provisional Patent application Ser. No. 61/136,292, filed Aug. 26, 2008, and U.S. patent application Ser. No. 12/325,028, filed Nov. 28, 2008, both entitled “SILICON CARBON NITRIDE ANTIREFLECTIVE COATING”, the contents of which are hereby incorporated by reference.

### FIELD OF THE INVENTION

This invention relates to silicon solar cells comprising an antireflective and passivation coating that comprises amorphous silicon carbonitride. The invention also relates to a process for preparing a silicon solar cell comprising the antireflective and passivation coating.

### BACKGROUND OF THE INVENTION

Plasma enhanced chemical vapour deposition (PECVD) deposited silicon nitride (SiN™) films [1,2] are widely used to provide a surface/bulk passivation and an anti-reflection coating (ARC) on phosphorus emitters. SiNₓ films provide excellent surface passivation on the emitter due to their highly positive fixed charge density, which induce an inversion or accumulation layer in Si under the SiNₓ. The optimum refractive index of the AR coating layer for an encapsulated solar cell is about 2.3, which is achievable by using silicon rich SiNₓ films. However, such films absorb light at short wavelengths, thereby reducing quantum efficiency. Recently, PECVD-deposited SiCₓ films have been studied for the surface passivation of crystalline silicon (c-Si) as surface recombination velocities (SRV) lower than 30 cm/sec have been reported at the SiCₓ/c-Si interface [3,4].

Silicon carbonitride films have also been shown to provide low effective surface recombination velocity on n-type crystalline silicon bulk structures, suggesting good passivation characteristics [7]. However, it is known in the art that selection of a dielectric passivation layer cannot be based solely on lifetime measurements of such test structures [8].

Silicon carbonitride films, prepared by hot wire deposition and comprising carbon concentrations greater than 40%, have also been investigated as passivation layers [9,10,11]. The solar cells obtained, however, suffered from poor contact formation (i.e. less than 74% Fill Factor) and displayed a strong dependence on firing temperature, passivation quality of the film degrading at temperatures above 700° C. Firing temperatures of up to 900° C. are often used during solar cell production.

### BRIEF SUMMARY OF THE INVENTION

In one aspect, the present invention provides a silicon solar cell comprising an antireflective and passivation coating, which coating comprises amorphous silicon carbonitride, wherein the amount of carbon in the silicon carbonitride is from 5 to 25 atomic %.

In a further aspect, the present invention provides a process for forming a silicon solar cell, comprising depositing by plasma-enhanced chemical vapour deposition (PECVD), on a silicon p-n junction, a gaseous mixture comprising a) one or more gaseous mono-silicon organosilanes and b) a nitrogen-containing gas.

In still a further aspect, the present invention provides a solar cell prepared by a process as defined herein.

The above and other features and advantages of the present invention will become apparent from the following description when taken in conjunction with the accompanying figures which illustrate preferred embodiments of the present invention by way of example.

### BRIEF DESCRIPTION OF THE DRAWINGS

Embodiments of the invention will be discussed with reference to the following Figures:

FIG. 1 displays the chemical composition (O, C, Si and N) of SiNₓ and SiCₓN_{y} films as a function of NH₃ flow rate.

FIG. 2 displays the hydrogen concentration in SiNₓ and SiCₓN_{y} films as a function of NH₃ flow rate.

FIG. 3 graphs the calculated photogeneration contours in mA/cm² as a function of bottom (n=2.6) and top (n=2.0) layer thicknesses for planar cells under 300-1200 nm, AM1.5G. No dispersion or absorption in the AR coating is assumed.

FIG. 4 displays the J_{oE} values, as a function of NH₃ gas flow rate, for silicon solar cells comprising SiNₓ and SiCₓN_{y} films on 45 ohm/sq emitters.

FIG. 5 displays the pre- and post-firing J_{oE} values, as a function of NH₃ gas flow rate, for silicon solar cells comprising SiNₓ and SiCₓN_{y} films on 45 ohm/sq emitters.

FIG. 6 graphs the surface charge densities of SiNₓ and SiCₓN_{y} films as a function of NH₃ gas flow rate.

FIG. 7 displays the pre- and post-firing Lifetime measurements, as a function of NH₃ gas flow rate, for SiNₓ and SiCₓN_{y} films prepared on 45 ohm/sq emitters.

FIG. 8 displays IQE responses and reflectance measurements of SiNₓ or SiCₓN_{y} antireflective coatings.

FIG. 9 graphs the efficiency of silicon solar cells bearing SiCₓN_{y} antireflective coatings as a function of the carbon concentration in the coating.

FIG. 10 graphs the refractive index of SiNₓ and SiCₓN_{y} films prepared with varying NH₃ gas flow rates.

FIG. 11 graphs the extinction coefficient of SiNₓ and SiCₓN_{y} films prepared with varying NH₃ gas flow rates.

FIG. 12 graphs the Fill Factor values for silicon solar cells comprising SiNₓ and SiCₓN_{y} films on 45 ohm/sq emitters, at varying NH₃ gas flow rates.

FIG. 13 graphs the Fill Factor values for silicon solar cells comprising SiNₓ and SiCₓN_{y} films on 60 ohm/sq emitters, at varying NH₃ gas flow rates.

FIG. 14 graphs the efficiency of silicon solar cells bearing SiCₓN_{y} antireflective coatings, prepared by remote plasma-enhanced chemical vapor deposition, as a function of the carbon concentration in the coating.

FIG. 15 graphs the carbon concentration of SiCₓN_{y} films prepared from gaseous mono-silicon organosilanes and NH₃ as precursors, as a function of the flow ratio of the precursors.

FIG. 16 graphs the refractive index of SiCₓN_{y} films prepared from gaseous mono-silicon organosilanes and NH₃ as precursors, as a function of the flow ratio of the precursors.

### DETAILED DESCRIPTION OF THE INVENTION

The present invention describes a silicon solar cell comprising an antireflective and passivation coating, which coating comprises amorphous silicon carbonitride, wherein the amount of carbon in the silicon carbonitride is from 5 to 25 atomic %, for example from 5 to 20 atomic %, from 5 to 19 atomic %, from 5 to 15 atomic %, from 10 to 19 atomic %, or from 14 to 18 atomic %. The amorphous silicon carbonitride is referred to herein as SiCₓN_{y}. The silicon carbonitride also comprises bonded or interstitial hydrogen atoms, the presence of which is understood in the term SiCₓN_{y}.

A silicon solar cell, as recited herein, means a wide area electronic device that converts solar energy into electricity by the photovoltaic effect, the device comprising a large-area p-n junction made from silicon. The cell also comprises ohmic metal-semiconductor contacts which are made to both the n-type and p-type sides of the solar cell, and one or more coatings that act as a passivation and antireflective coating. Examples of silicon solar cells include amorphous silicon cells [12], amorphous silicon-polycrystalline silicon tandem cells [13], silicon-silicon/germanium tandem cells [14], string ribbon cells [15], PERC cells [16], and PERL cells [17].

### ARC Composition

In one embodiment, the atomic % range for Si in the SiCₓN_{y} ARC is from about 25% to about 70%, for example from about 30% to about 60%, from about 30 to about 35%, or from about 31% to about 34%.

In another embodiment, the atomic % range for H in the SiCₓN_{y} ARC is from about 10% to about 40%, for example from about 15% atomic % to about 35%, from about 20 to about 30% or from about 22 to about 28%.

In another embodiment, the atomic % range for N in SiCₓN_{y} is up to about 65%, for example from about 10% to about 60%, from about 20% to about 40%, or from about 25% to about 35%.

In a further embodiment, the film can also comprise other atomic components as dopants. For example, the doped-film can comprise F, Al, B, Ge, Ga, P, As, O, In, Sb, S, Se, Te, In, Sb or a combination thereof.

The thickness of the film can be selected based on the optical and physical characteristics desired for the prepared ARC. In one embodiment, the thickness is selected in order to obtain a reflection minima at a light wavelength of about 600-650 nm. For example a refractive index of 2 with a thickness of 75 nm can be considered optimum, although small variations in thickness may not greatly affect the refractive index. In one embodiment, the SiCₓN_{y} ARC will have thickness from about 50 to about 160 nm, e.g. from about 50 to about 100 nm or from about 70 to about 80 nm.

In one embodiment, the antireflective coating comprises only a SiCₓ layer. In another embodiment, the antireflective coating comprises a multiplicity of layers, at least one of which is a SiCₓN_{y} layer as described herein. In yet another embodiment, the antireflective coating comprises a SiCₓN_{y} layer as described herein, which layer displays a graded refractive index through its thickness.

### Conversion Efficiency

A solar cell's energy conversion efficiency is the percentage of power converted (from absorbed light to electrical energy) and collected, when a solar cell is connected to an electrical circuit. Standard test conditions (STC) specify a temperature of 25° C. and an irradiance of 1000 W/m² with an air mass 1.5 (AM1.5) spectrum. These correspond to the irradiance and spectrum of sunlight incident on a clear day upon a sun-facing 37°-tilted surface with the sun at an angle of 41.81° above the horizon. This condition approximately represents solar noon near the spring and autumn equinoxes in the continental United States with surface of the cell aimed directly at the sun. Thus, under these conditions a solar cell of 12% efficiency with a 100 cm² (0.01 m²) surface area can be expected to produce approximately 1.2 watts of power.

The losses of a solar cell may be broken down into reflectance losses, thermodynamic efficiency, recombination losses and resistive electrical loss. The overall efficiency is the product of each of these individual losses. Due to the difficulty in measuring these parameters directly, other parameters are measured instead, such as: Quantum Efficiency, V_{OC} ratio, J_{SC}, Jₒ, J_{oE} and Fill Factor. Reflectance losses are a portion of the Quantum Efficiency under “External Quantum Efficiency”. Recombination losses make up a portion of the Quantum Efficiency, V_{OC} ratio, and Fill Factor (FF). Resistive losses are predominantly categorized under Fill Factor, but also make up minor portions of the Quantum Efficiency and V_{OC} ratio.

### Quantum Efficiency

When a photon is absorbed by a solar cell it is converted to an electron-hole pair. This electron-hole pair may then travel to the surface of the solar cell and contribute to the current produced by the cell; such a carrier is said to be collected. Alternatively, the carrier may give up its energy and once again become bound to an atom within the solar cell without reaching the surface; this is called recombination, and carriers that recombine do not contribute to the production of electrical current.

Quantum efficiency refers to the percentage of photons that are converted to electric current (i.e., collected carriers) when the cell is operated under short circuit conditions. Quantum efficiency can be quantified by the equation:

Quantum efficiency=J_{sc}·V_{oc}·FF/Pᵢₙ

External quantum efficiency is the fraction of incident photons that are converted to electrical current, while internal quantum efficiency is the fraction of absorbed photons that are converted to electrical current. Mathematically, internal quantum efficiency is related to external quantum efficiency by the reflectance of the solar cell; given a perfect anti-reflection coating, they are the same.
V_{OC} ratio

V_{OC} depends on J_{sc} and J_{oE}, where J_{sc} is the short circuit current density and J_{oE} is the emitter saturation current density. Mathematically, V_{oc}=(kT/q)·ln(J_{sc}/J_{sc}/J_{oE}+1). J_{oE} can depend on Auger recombination losses, defects related recombination losses and the level of emitter doping. Due to recombination, the open circuit voltage (V_{OC}) of the cell will be below the band gap voltage (V_{g}) of the cell. Since the energy of the photons must be at or above the band gap to generate a carrier pair, cell voltage below the band gap voltage represents a loss. This loss is represented by the ratio of V_{OC} divided by V_{g}.

maximum-power point

A solar cell may operate over a wide range of voltages (V) and currents (I). By increasing the resistive load on an irradiated cell continuously from zero (a short circuit) to a very high value (an open circuit) one can determine the maximum-power point, the point that maximizes V×I; that is, the load for which the cell can deliver maximum electrical power at that level of irradiation (the output power is zero in both the short circuit and open circuit extremes).

### Fill Factor and Rshunt

Another defining term in the overall behaviour of a solar cell is the Fill Factor (FF). This is the ratio of the actual obtainable power (maximum power point) divided by the theoretically obtainable power (based on the open circuit voltage (V_{OC}) and the short circuit current (Isc). The Fill factor is thus defined as (VₘₚIₘₚ)/(V_{oc}I_{sc}), where Iₘₚ and Vₘₚ represent the current density and voltage at the maximum power point.

Rshunt (R_{SH}) is also indicative of cell performance since, as shunt resistance decreases, the flow of current diverted through the shunt resistor increases for a given level of junction voltage, producing a significant decrease in the terminal current I and a slight reduction in V_{oc}. Very low values of R_{SH} will produce a significant reduction in V_{oc}. Much as in the case of a high series resistance, a badly shunted solar cell will take on operating characteristics similar to those of a resistor.

High values for Fill Factor, together with high Rshunt values, indicate that quality of the contact formed on solar cell is high. While quality of the contact will also depend in part on other factors, such as the nature of the p-n emitter and the process used to form the contact, a major contributor to Fill Factor is the nature of the antireflective coating, through which the contact must be made. As an estimate, a 0.5% improvement in Fill Factor leads to ˜0.1% increase in cell efficiency, and such an increase in efficiency can be equated to a substantial increase in profitability for solar cell production.

### Passivation

It is beneficial for the long-term stability of the efficiency of a solar cell that the surface passivation capability of the solar cell does not degrade under extended exposure to sunlight. The ARC should therefore be able to passivate defects in the surface or near-surface region of the solar cell due to earlier processing steps (e.g. saw damage; etch damage, dangling bonds, etc. . . . ). Poorly passivated surfaces reduce the short circuit current (Isc), the open circuit voltage (V_{OC}), and the internal quantum efficiency, which in turn reduces the efficiency of the solar cell. The ARC film can reduce the recombination of charge carriers at the silicon surface (surface passivation), which is particularly important for high efficiency and thin solar cells (e.g. cells having a thickness <200 μm). Bulk passivation is also important for multicrystalline solar cells, and it is believed that high hydrogen content in the ARC film can induce bulk passivation of various built-in electronic defects (impurities, grain boundaries, etc.) in the multicrystalline (mc) silicon bulk material. The SiCₓN_{y} films of the present invention naturally contain bonded and/or interstitial hydrogen atoms, and they display good passivation characteristics.

Characterization of the SiCₓN_{y} ARC

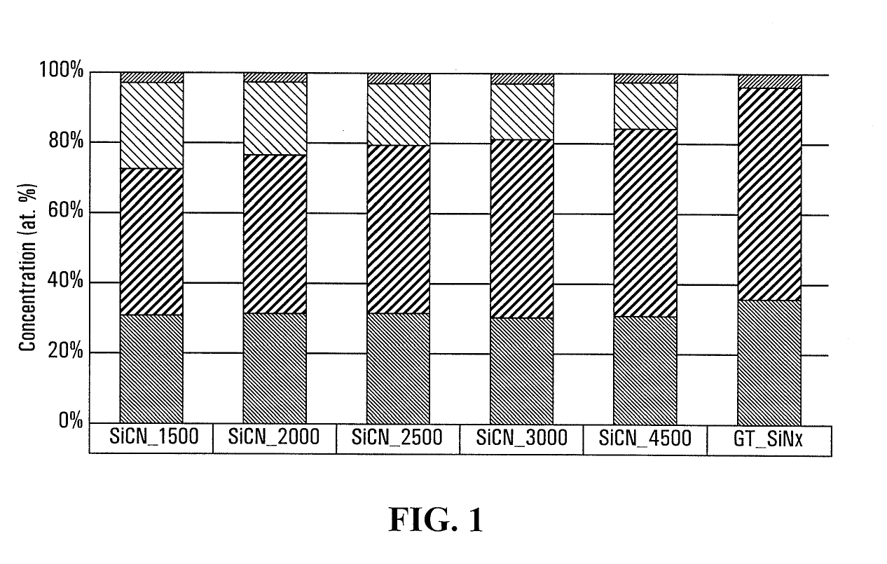

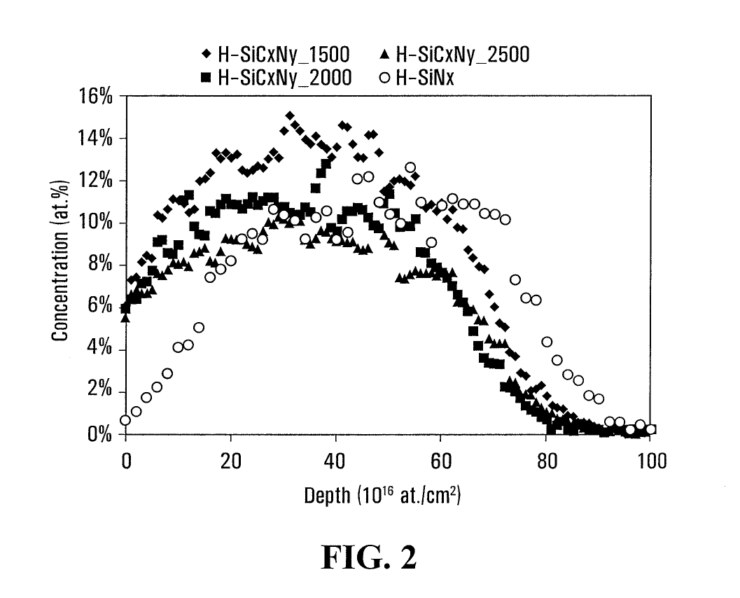

The Si/C/N chemical composition and hydrogen content of SiNₓ and SiCₓN_{y} films, as a function of NH₃ flow rate during film deposition, are displayed in FIGS. 1 and 2, respectively.

Other deposition parameters including the flow rate of silicon source, deposition temperature, pressure, and plasma power were fixed for all the depositions shown in the Figures. From FIGS. 1 and 2, it can be seen that with increases in NH₃ flow, the carbon and hydrogen contents in the SiCₓN_{y} film decrease and the nitrogen content increases. The silicon fraction was found to be constant regardless of the NH₃ flow rate, meaning that the carbon composition can be varied by adjusting the flow rate of NH₃ gas, without affecting the silicon composition. Accordingly, the chemical compositions of the dielectric films approach to those of the SiNₓ coating as the NH₃ flow rate increases. From FIG. 2, it can be noted that hydrogen content in some embodiments of SiCₓN_{y} is higher than in SiNₓ, indicating that SiCₓN_{y} may supply enough hydrogen to passivate defects in bulk silicon during contact firing.

In one embodiment, the SiCₓN_{y} ARC of the invention can have a refractive index (n) at a wavelength of 630 nm of 1.8 to 2.3, for example a refractive index of 2.05, and an extinction coefficient (k) at a wavelength of 300 nm of less than 0.01, for example less than 0.001. From Table 7 in the experimental section, it can be seen that the refractive index is reduced with increased nitrogen content in the films. It is expected that wider range of refractive index can be achieved by either changing the nature of the gaseous reactants used to prepare the ARC, and/or the NH₃ gas flow rate.

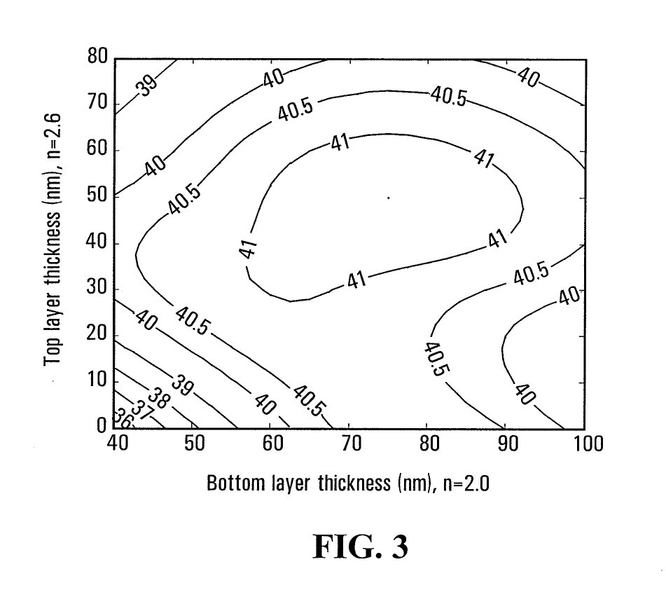

The SiCₓN_{y} can also be combined to form a double layer ARC. As shown in FIG. 3, the double layer ARC should provide improvement in short circuit current density (J_{sc}).

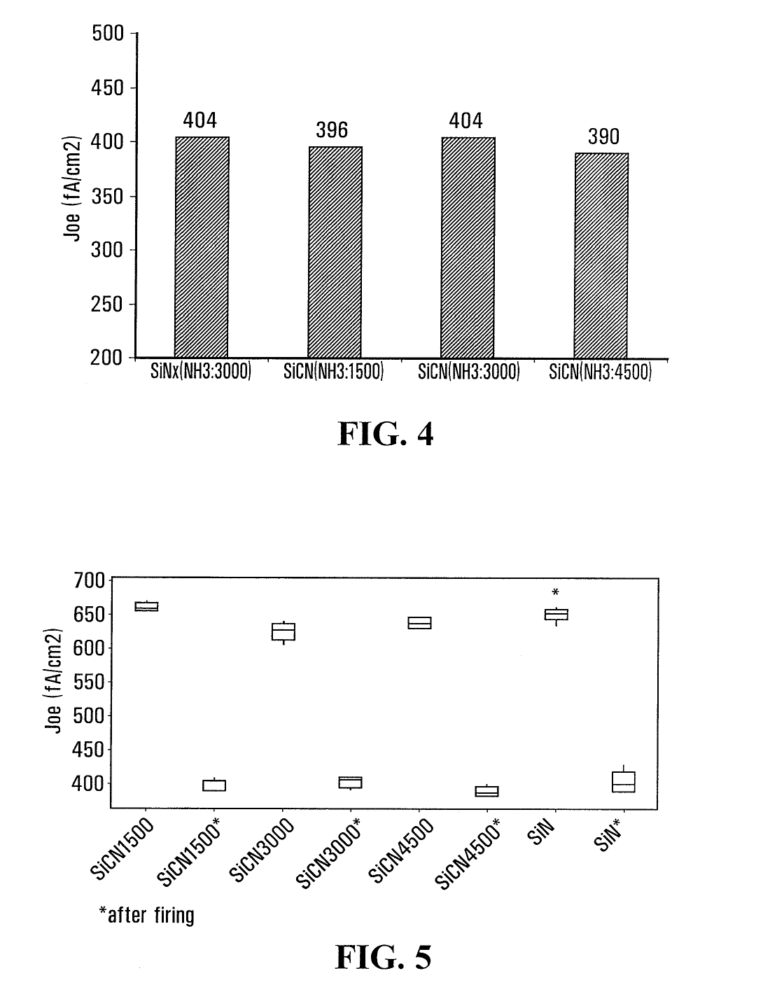

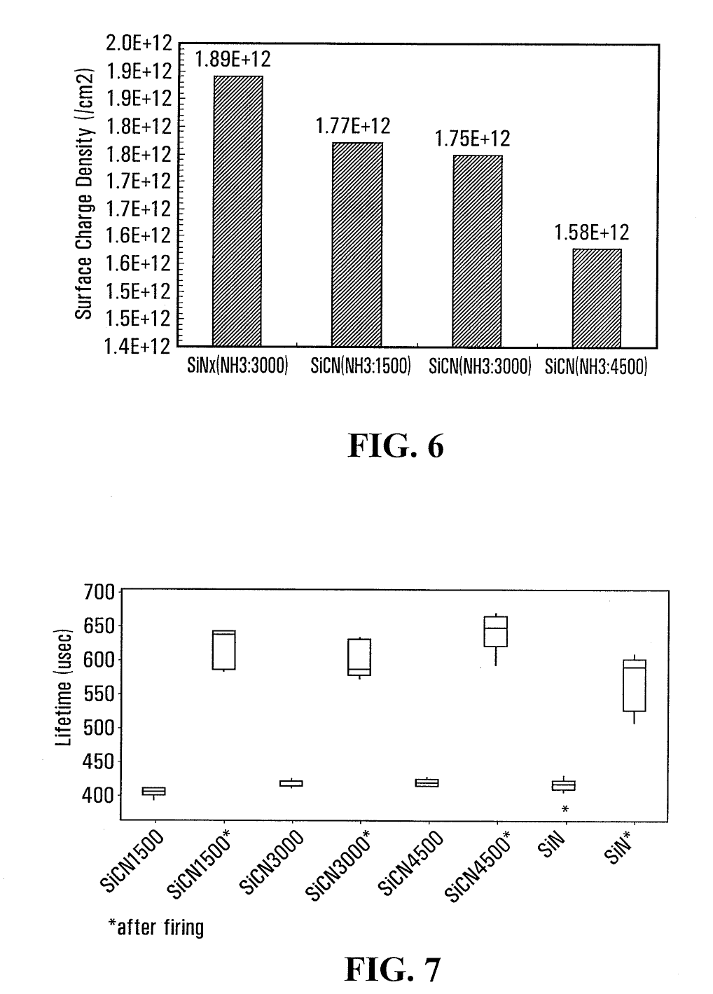

J_{oE} values were also measured on 45 ohm/sq textured emitters in order to study electrical properties of SiCₓN_{y} films coated with different NH₃ gas flow rates and compared with those of SiNₓ films, as shown in FIGS. 4 and 5. The J_{oE} values between SiNₓ and SiCₓN_{y} films were fairly constant, regardless of NH₃ gas flow rate used in their preparation, indicating that SiCₓN_{y} can provide an excellent cell performance when used for the front surface passivation of Si solar cells. As shown in FIG. 6, the surface charge densities (Q_{FB}) in the SiCₓN_{y} films after annealing was measured to be slightly lower than that of the SiNₓ film. The surface charge density plays a critical role to the surface passivation as well as to device performance [5,6]. However, from FIG. 7, where lifetime measurements for SiCₓNₓ and SiNₓ films (pre- and post-firing) are displayed, we see that passivation obtained with the SiCₓNₓ film is similar to or greater than the passivation for the SiNₓ film. From these results, it would appear that the comparable J_{oE} values shown in FIGS. 4 and 5 for SiCₓNₓ and SiNₓ films are in both cases caused by highly positive surface charge density and relatively high hydrogen concentration.

The SiCₓN_{Y} films were applied to solar cell fabrication to compare their performance with that of a conventional PECVD SiNₓ film. Cell efficiencies above 16.8% were achieved on the solar cells with SiCₓN_{y} AR coatings, and both the SiNₓ and SiCₓN_{y} of films provided comparable Jₛ, and V_{oc} values. It would appear that the comparable J_{sc} and V_{oc}, can be attributed to high-quality optical and electrical properties of the SiCₓN_{y} films. However, improvements in Fill Factor (FF) and Rshunt (R_{SH}) values were observed for SiCₓN_{y} films. Without being bound by theory, it is believed that the higher FF and R_{SH} values shown by the SiCₓN_{y} AR coatings may be related to the etching behaviour of the glass frit in the Ag paste used to make the better contacts. During contact formation, lead borosilicate glass melts and etches the antireflective coating. A redox reaction between PbO and Si also takes place, forming liquid Pb, which then dissolves Ag and Si to etch the emitter surface. The presence of carbon in the antireflective coating likely affects this redox reaction, which potentially provides better contact formation between metal (Ag) and semiconductor (Si), as suggested by the increase Fill Factor and Rshunt values observed.

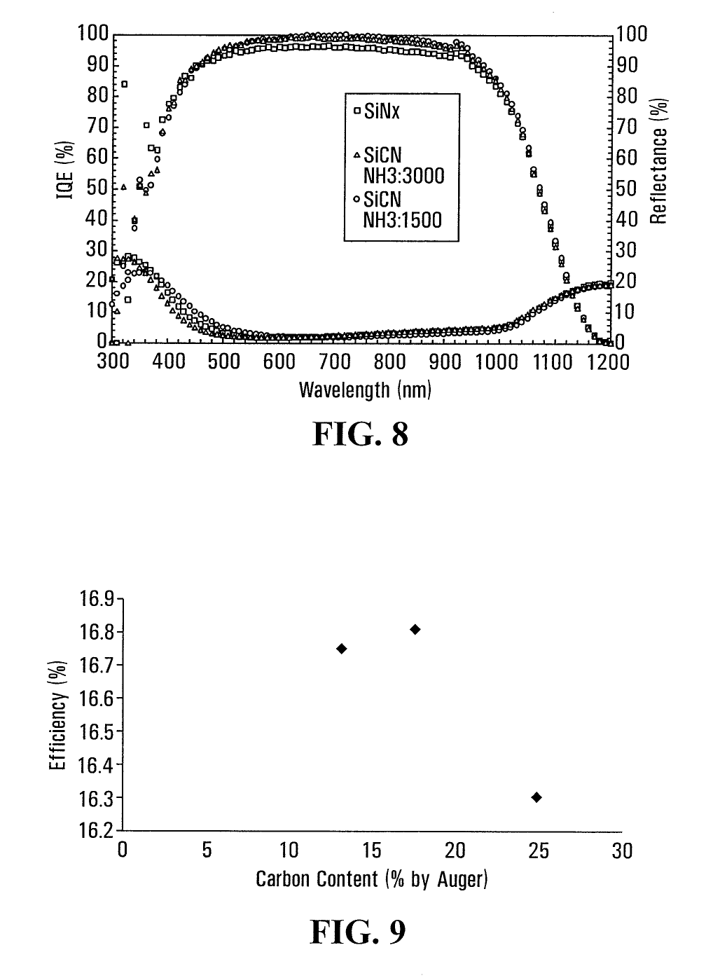

The internal quantum efficiency (IQE) and reflectance values of the solar cells with the SiNₓ and SiCₓN_{y} ARCs were also measured (FIG. 8). From short and long wave length responses, SiCₓN_{y} films were shown to provide a high surface passivation quality without hurting bulk lifetime.

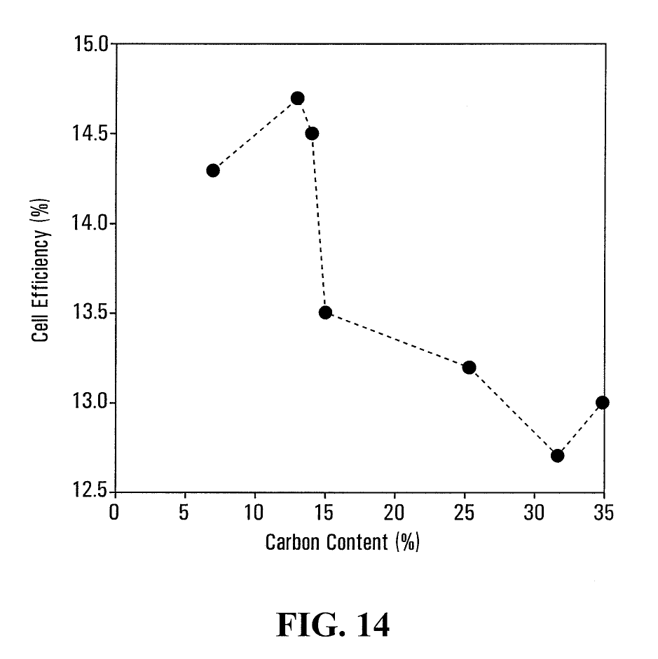

The efficiency of silicon solar cells comprising SiCₓN_{y} antireflective coatings as a function of the carbon content is displayed in FIGS. 9 and 14. From the Figures, it can be seen that there appears to be an advantageous range for the carbon content in the SiCₓN_{y} film.

### Preparation of the SiCₓN_{y} ARC

In one aspect, the invention provides a process for preparing SiCₓN_{y} anti-reflective coatings of the invention.

In one embodiment, the ARC film can be prepared by plasma enhanced chemical vapour deposition of gaseous species comprising Si, C, N and H atoms.

While it is possible to combine all of the required Si, C, N and H atoms within a single gaseous species, two or more gases, collectively comprising the required atomic species, can be combined and reacted under PE-CVD conditions.

In one embodiment, the required C and Si atoms are contained in separate gases, while in another embodiment the C and Si atoms are contained in a single gaseous species. For example, the SiCₓN_{y} ARC can be prepared from a mixture of SiH₄, a gaseous source of nitrogen (e.g. NH₃ or N₂), and a gaseous hydrocarbon (e.g. methane), which gases are mixed and exposed to an energy enhanced CVD instrument. Alternately, a gaseous organosilicon compounds (e.g. an organosilane and/or an organopolycarbosilane), mixed with a gaseous source of nitrogen (e.g. NH₃, N₂, or NCl₃) and exposed to PE-CVD conditions can yield the SiCₓN_{y} ARC. The gaseous organosilicon compounds can be obtained commercially in gas form (and admixed if required), or they can be prepared (optionally in-situ) from solid precursors.

Gaseous Organosilicon Compounds from Solid Precursors

In one embodiment, the gaseous organosilanes and/or organopolycarbosilanes can be obtained from thermal decomposition/rearrangement (i.e. pyrolysis) or volatilisation of a solid organosilane source. The solid organosilane source can be any compound that comprises Si, C and H atoms and that is solid at room temperature and pressure.

The solid organosilane source may, in one embodiment, be a silicon-based polymer comprising Si—C bonds that are thermodynamically stable during heating in a heating chamber. In one embodiment, the silicon-based polymer has a monomeric unit comprising at least one silicon atom and two or more carbon atoms. The monomeric unit may further comprise additional elements such as N, O, F, or a combination thereof. In another embodiment, the polymeric source is a polysilane or a polycarbosilane.

The polysilane compound can be any solid polysilane compound that can produce gaseous organosilicon compounds when pyrolyzed, i.e. chemical decomposition of the solid polysilane by heating in an atmosphere that is substantially free of molecular oxygen. In one embodiment, the solid polysilane compound comprises a linear or branched polysilicon chain wherein each silicon is substituted by one or more hydrogen atoms, C₁-C₆ alkyl groups, phenyl groups or —NH₃ groups. In a further embodiment, the linear or branched polysilicon chain has at least one monomeric unit comprising at least one silicon atom and one or more carbon atoms. In another embodiment, the linear or branched polysilicon chain has at least one monomeric unit comprising at least one silicon atom and two or more carbon atoms.

Examples of solid organosilane sources include silicon-based polymers such as polydimethylsilane (PDMS) and polycarbomethylsilane (PCMS), and other non-polymeric species such as triphenylsilane or nonamethyltrisilazane. PCMS is commercially available (Sigma-Aldrich) and it can have, for example, an average molecular weight from about 800 Daltons to about 2,000 Daltons. PDMS is also commercially available (Gelest, Morrisville, Pa. and Strem Chemical, Inc., Newburyport, Mass.) and it can have, for example, an average molecular weight from about 1,100 Daltons to about 1,700 Dalton. Use of PDMS as a source compound is advantageous in that (a) it is very safe to handle with regard to storage and transfer, (b) it is air and moisture stable, a desirable characteristic when using large volumes of a compound in an industrial environment, (c) no corrosive components are generated in an effluent stream resulting from PDMS being exposed to CVD process conditions, and (d) PDMS provides its own hydrogen supply by virtue of its hydrogen substituents.

In another embodiment, the solid organosilane source may have at least one label component, the type, proportion and concentration of which can be used to create a chemical “fingerprint” in the obtained film that can be readily measured by standard laboratory analytical tools, e.g. Secondary Ion Mass Spectrometry (SIMS), Auger Electron Spectrometry (AES), X-ray photoelectron spectroscopy (XPS). In one embodiment, the solid organosilane source can contain an isotope label, i.e. a non-naturally abundant relative amount of at least one isotope of an atomic species contained in the solid organosilane source, e.g. C¹³ or C¹⁴. This is referred to herein as a synthetic ratio of isotopes.

### Pyrolysis/Volatilization of the Solid Precursor

In one embodiment, the gaseous organosilicon species are formed by pyrolysis of the solid organosilane source in a heating chamber. The solid source may be added to the heating chamber in a batch or continuous manner as a powder, pellet, rod or other solid form. Optionally, the solid organosilane source may be mixed with a second solid polymer in the heating chamber. In batch addition, the solid organosilane source compound may be added, for example, in an amount in the range of from 1 mg to 10 kg, although larger amounts may also be used.

In one embodiment the heating chamber is purged, optionally under vacuum, after the solid organosilane source has been added, to replace the gases within the chamber with an inert gas, such as argon or helium. The chamber can be purged before heating is commenced, or the temperature within the chamber can be increased during, or prior to, the purge. The temperature within the chamber during the purge should be kept below the temperature at which evolution of the gaseous species commences to minimise losses of product.

The pyrolysis step can encompass one or more different types of reactions within the solid. The different types of reactions, which can include e.g. decomposition/rearrangement of the solid organosilane into a new gaseous and/or liquid organosilane species, will depend on the nature of the solid organosilane source, and these reactions can also be promoted by the temperature selected for the pyrolysis step. Control of the above parameters can also be used to achieve partial or complete volatilisation of the solid organosilane source instead of pyrolysis (i.e. instead of decomposition/rearrangement of the organosilane source). The term “pyrolysis”, as used herein, is intended to also capture such partial or complete volatilizatioin.

For embodiments where the solid organosilane source is a polysilane, the gaseous species can be obtained through a process as described in U.S. provisional application Ser. No. 60/990,447 filed on Nov. 27, 2007, the disclosure of which is incorporated herein by reference in its entirety.

The heating of the solid organosilane source in the heating chamber may be performed by electrical heating, UV irradiation, IR irradiation, microwave irradiation, X-ray irradiation, electronic beams, laser beams, induction heating, or the like.

The heating chamber is heated to a temperature in the range of, for example, from about 50 to about 700° C., from about 100 to about 700° C., from about 150 to about 700° C., from about 200 to about 700° C., from about 250 to about 700° C., from about 300 to about 700° C., from about 350 to about 700° C., from about 400 to about 700° C., from about 450 to about 700° C., from about 500 to about 700° C., from about 550 to about 700° C., about 600 to about 700° C., from about 650 to about 700° C., from about 50 to about 650° C., from about 50 to about 600° C., from about 50 to about 550° C., from about 50 to about 500° C., from about 50 to about 450° C., from about 50 to about 400° C., from about 50 to about 350° C., from about 50 to about 300° C., from about 50 to about 250° C., from about 50 to about 200° C., from about 50 to about 150° C., from about 50 to about 100° C., from about 100 to about 650° C., from about 150 to about 600° C., from about 200 to about 550° C., from about 250 to about 500° C., from about 300 to about 450° C., from about 350 to about 400° C., from about 475 to about 500° C., about 50° C., about 100° C., about 150° C., about 200° C., about 250° C., about 300° C., about 350° C., about 400° C., about 450° C., about 500° C., about 550° C., about 600° C., about 650° C., or about 700° C. A higher temperature can increase the rate at which the gaseous compounds are produced from the solid organosilane source.

In one embodiment, the heating chamber is heated at a rate of up to 150° C. per hour until the desired temperature is reached, at which temperature the chamber is maintained. In another embodiment, the temperature is increased to a first value at which pyrolysis proceeds, and then the temperature is changed on one or more occasion, e.g. in order to vary the rate at which the mixture of gaseous compound is produced or to vary the pressure within the chamber.

In one embodiment the temperature and pressure within the heating chamber are controlled, and production of the gaseous species can be driven by reducing the pressure, by heating the organosilane source, or by a combination thereof. Selection of specific temperature and pressure values for the heating chamber can also be used to control the nature of the gaseous species obtained.

In the embodiment where the solid organosilane source is a polysilane, one possible pyrolysis reaction leads to the formation of Si—Si crosslinks within the solid polysilane, which reaction usually takes place up to about 375° C. Another possible reaction is referred to as the Kumada rearrangement, which typically occurs at temperatures between about 225° C. to about 350° C., wherein the Si—Si backbone chain becomes a Si—C—Si backbone chain. While this type of reaction is usually used to produce a non-volatile product, the Kumada re-arrangement can produce volatile polycarbosilane oligomers, silanes and/or methyl silanes. While the amount of gaseous species produced by way of the Kumada rearrangement competes with the production of non-volatile solid or liquid polycarbosilane, the production of such species, while detrimental to the overall yield, can prove a useful aspect of the gas evolution process in that any material, liquid or solid, that is left in the heating chamber is in some embodiments turned into a harmless and safe ceramic material, leading to safer handling of the material once the process is terminated.

### Gaseous Organosilicon Species

Generally, the gaseous organosilicon species prepared from solid organosilanes comprise a mixture of volatile fragments of the organosilane. In the embodiment where the solid organosilane precursor is a polysilane, the gaseous species are a mixture of gaseous organosilicon compounds, i.e. compounds comprising silicon, carbon and hydrogen atoms that are in the gas phase at 20° C. and 20 psi.

In one embodiment, the mixture of gaseous organosilicon compounds substantially comprises one or more gaseous silanes (i.e. gaesous compounds comprising a single silicon atom). These are also referred to herein as gaseous mono-silicon organosilanes, examples of such include methyl silane, dimethyl silane, trimethyl silane and tetramethyl silane.

In one embodiment, the gaseous mixture can also optionally comprise small amounts (e.g. less than 10%) of gaseous multi-silicon species, such as gaseous polysilanes, or gaseous polycarbosilanes. By gaseous polysilane is meant a compound comprising two or more silicon atoms wherein the silicon atoms are covalently linked (e.g. Si—Si), and by gaseous polycarbosilane is meant a compound comprising two or more silicon atoms wherein at least two of the silicon atoms are linked through a non-silicon atom (e.g. Si—CH₂—Si). Examples of gaseous polycarbosilanes can have the formula:

Si(CH₃)ₙ(H)ₘ—[(CH₂)—Si(CH₃)ₚ(H)_{q}]ₓ—Si(CH₃)_{n′}(H)_{m′}

wherein n, m, n′ and m′ independently represent an integer from 0 to 3, with the proviso that n+m=3 and n′+m′=3; p and q independently represent an integer from 0 to 2, with the proviso that p+q=2 for each silicon atom; and x is an integer from 0 to 3. Further examples of gaseous polycarbosilanes include [Si(CH₃)(H)₂]—CH₂—[Si(CH₃)₂(H)], [Si(CH₃)₂(H)]—CH₂—[Si(CH₃)₂(H)], [Si(CH₃)₃]—CH₂—[Si(CH₃)₂ (H)], [Si(CH₃)₂ (H)]—CH₂—[Si(CH₃)₂]—CH₂—[Si(CH₃)₃], [Si(CH₃)(H)₂]—CH₂—[Si(CH₃)₂]—CH₂—[Si(CH₃)(H)₂], [Si(CH₃)(H)₂]—CH₂—[Si(CH₃)₂]—CH₂—[Si(CH₃)₂ (H)], [Si(CH₃)₂ (H)]—CH₂—[Si(CH₃)₂]—CH₂—[Si(CH₃)₂ (H)], [Si(CH₃)₂ (H)]—CH₂—[Si(CH₃)₂]—CH₂—[Si(CH₃)₂]—CH₂—[Si(CH₃)₂ (H)], [Si(CH₃)(H)₂]—CH₂—[Si(CH₃)₂]—CH₂—[Si(CH₃)₂]—CH₂—[Si(CH₃)₂ (H)], [Si(CH₃)(H)₂]—CH₂—[Si(CH₃)₂]—CH₂—[Si(CH₃)₂]—CH₂—[Si(CH₃)(H)₂], and [Si(H)₃]CH₂[Si(CH₃)₂]—CH₂—[Si(CH₃)₂]—CH₂— [Si(CH₃)(H)₂].

In one embodiment, the gaseous species is a mixture comprising from 20 to 45 wt. % methylsilane, from 35 to 65 wt. % dimethylsilane, from 5 to 15 wt. % trimethylsilane, and optionally up to 10 wt. % gaseous carbosilane species.

After forming the gaseous species, it may be used immediately or stored under appropriate temperature and pressure conditions for later use. The process may be interrupted at this stage since the heating chamber may be external to the reactor.

### Addition of a Reactant Gas

The gaseous species used to form the SiCₓN_{y} may be mixed with a reactant gas in the deposition chamber, in a gas mixing unit, or when pyrolysis is used to obtain the gaseous species, in the heating chamber. In one embodiment, the reactant gas may be in the form of a gas that is commercially available, and the gas is provided directly to the system. In another embodiment, the reactant gas is produced by heating a solid or liquid source comprising any number of elements, such as O, F, or a combination thereof.

In one example, the reactant gas may be an oxygen-based gas such as CO, O₂, O₃, CO₂ or a combination thereof.

In an embodiment, the reactant gas may also comprise F, Al, B, Ge, Ga, P, As, In, Sb, S, Se, Te, In and Sb in order to obtain a doped SiCₓN_{y} film.

### Deposition Chamber

When it is desired to form a film, a substrate is placed into a deposition chamber, which is evacuated to a sufficiently low pressure, and the gaseous species and optionally a carrier gas are introduced continuously or pulsed. Any pressure can be selected as long as the energy source selected to effect the deposition can be used at the selected pressure. For example, when plasma is used as the energy source, any pressure under which plasma can be formed is suitable. In embodiments of the present invention the pressure can be from about 50 to about 4000 mTorr, from about 100 to about 500 mTorr, from about 150 to about 500 mTorr, from about 200 to about 500 mTorr, from about 200 to about 500 mTorr, from about 250 to about 500 mTorr, from about 300 to about 500 mTorr, from about 350 to about 500 mTorr, from about 400 to about 500 mTorr, from about 450 to about 500 mTorr, from about 50 to about 450 mTorr, from about 50 to about 400 mTorr, from about 50 to about 350 mTorr, from about 50 to about 300 mTorr, from about 50 to about 250 mTorr, from about 50 to about 200 mTorr, from about 50 to about 150 mTorr, from about 50 to about 100 mTorr, from about 100 to about 450 mTorr, from about 150 to about 400 mTorr, from about 200 to about 350 mTorr, from about 250 to about 300 mTorr, from about 50 mTorr to about 5 Torr, from about 50 mTorr to about 4 Torr, from about 50 mTorr to about 3 Torr, from about 50 mTorr to about 2 Torr, from about 50 mTorr to about 1 Torr, about 50 mTorr, about 100 mTorr, about 150 mTorr, about 200 mTorr, about 250 mTorr, about 300 mTorr, about 350 mTorr, about 400 mTorr, about 450 mTorr, about 500 mTorr, about 1 Torr, about 2 Torr, about 3 Torr, about 4 Torr, or about 5 Torr.

The substrate is held at a temperature in the range of, for example, from about 25 to about 500° C., from about 50 to about 500° C., from about 100 to about 500° C., from about 150 to about 500° C., from about 200 to about 500° C., from about 250 to about 500° C., from about 300 to about 500° C., from about 350 to about 500° C., from about 400 to about 500° C., from about 450 to about 500° C., from about 25 to about 450° C., from about 25 to about 400° C., from about 25 to about 350° C., from about 25 to about 300° C., from about 25 to about 250° C., from about 25 to about 200° C., from about 25 to about 150° C., from about 25 to about 100° C., from about 25 to about 50° C., from about 50 to about 450° C., from about 100 to about 400° C., from about 150 to about 350° C., from about 200 to about 300° C., about 25° C., about 50° C., about 100° C., about 150° C., about 200° C., about 250° C., about 300° C., about 350° C., about 400° C., about 450° C., or about 500° C.

Any system for conducting energy induced chemical vapour deposition may be used for the method of the present invention, and other suitable equipment will be recognised by those skilled in the art. The typical equipment, gas flow requirements and other deposition settings for a variety of PECVD deposition tools used for commercial coating solar cells can be found in True Blue, Photon International, March 2006 pages 90-99 inclusive, the contents of which are enclosed herewith by reference.

The energy source in the deposition chamber may be, for example, electrical heating, hot filament processes, UV irradiation, IR irradiation, microwave irradiation, X-ray irradiation, electronic beams, laser beams, plasma, or RF.

In a preferred embodiment, the energy source is plasma, and examples of suitable plasma deposition techniques include plasma enhanced chemical vapour deposition (PECVD), radio frequency plasma enhanced chemical vapour deposition (RF-PECVD), electron-cyclotron-resonance plasma-enhanced chemical-vapour deposition (ECR-PECVD), inductively coupled plasma-enhanced chemical-vapour deposition (ICP-ECVD), plasma beam source plasma enhanced chemical vapour deposition (PBS-PECVD), or combinations thereof. Furthermore, other types of deposition techniques suitable for use in manufacturing integrated circuits or semiconductor-based devices may also be used.

For embodiments where the energy used during the deposition is plasma, e.g. for PE-CVD, characteristics of the obtained film may be controlled by suitably selecting conditions for (1) the generation of the plasma, (2) the temperature of the substrate, (3) the power and frequency of the reactor, and (4) the type and amount of gaseous species introduced into the deposition chamber.

### Configuration of Heating and Deposition Chambers

In those embodiments where the gaseous organosilicon species is obtained from the pyrolysis of a solid source, the process may be carried with a variety of system configurations, such as a heating chamber and a deposition chamber; a heating chamber, a gas mixing unit and a deposition chamber; a heating chamber, a gas mixing unit and a plurality of deposition chambers; or a plurality of heating chambers, a gas mixing unit and at least one deposition chamber. In a preferred embodiment, the deposition chamber is within a reactor and the heating chamber is external to the reactor.

For high throughput configurations, multiple units of the heating chamber may be integrated. Each heating chamber in the multiple-unit configuration may be of a relatively small scale in size, so that the mechanical construction is simple and reliable. All heating chambers may supply common gas delivery, exhaust and control systems so that cost is similar to a larger conventional reactor with the same throughput. In theory, there is no limit to the number of reactors that may be integrated into one system.

The process may also utilize a regular mass flow or pressure controller to more accurately deliver appropriate process demanded flow rates. The gaseous species may be transferred to the deposition chamber in a continuous flow or in a pulsed flow.

The process may in some embodiments utilize regular tubing without the need of special heating of the tubing as is the case in many liquid source CVD processes in which heating the tubing lines is essential to eliminate source vapour condensation, or earlier decomposition of the source.

### EXAMPLES

The following examples are provided to illustrate the invention. It will be understood, however, that the specific details given in each example have been selected for purpose of illustration and are not to be construed as limiting the scope of the invention. Generally, the experiments were conducted under similar conditions unless noted.

The antireflective coatings were deposited using a “Coyote” PECVD system manufactured by Pacific Western. The PECVD deposition was carried out at a substrate temperature of 425° C. to 475° C., a pressure of 2 Torr, a power of 150 W, and an RF power frequency of 50 kHz. The flow of gaseous organosilicon compound into the PECVD instrument was maintained at 300 sccm (silane equivalent mass flow conditions), and the flow of ammonia was maintained between 1500-4500 sccm. Separate depositions were also made using a Roth and Rau AK400 remote plasma tool.

Optical properties of the dielectric films were characterized by a spectroscopic ellipsometer (Woollam Co.). The composition of the dielectric films was analyzed by XPS (X-ray photoelectron spectroscopy) and Elastic Recoil Detection (ERD). Saw damage on the as-cut wafers was removed by etching in potassium hydroxide (KOH) solution followed by anisotropic etching in the mixture of KOH and isopropyl alcohol (IPA) for texturing. The textured silicon wafers were cleaned in 2:1:1 H₂O:H₂O₂:H₂SO₄ and 2:1:1 H₂O: H₂O₂:HCl solutions followed by phosphorus diffusion in a quartz tube to form 45 and 60 Ω/sq emitters.

For comparative purposes, a conventional SiNₓ AR coating layer with a thickness of 75 nm and a refractive index of ˜2.05 was deposited in the same low-frequency (50 KHz) PECVD reactor (Coyote). The SiNₓ depositions were made at a SiH₄:NH₃ ratio of 300:3000 sccm.

Silicon carbonitride films were deposited in the same chamber using ammonia and gas generated from a solid PDMS source. The solid source was heated inside a sealed pressure vessel. The gas evolved from the PDMS was supplied to the PECVD reactor via standard silane mass flow controllers (MFC) and flow was controlled assuming the same correction factor as for silane. No gas condensation problems were observed in the gas delivery system. The carrier lifetimes in the wafers and emitter saturation current density (J_{oE}) of the diffused emitters were measured using Sinton's quasi-steady-state photoconductance (QSSPC) tool. The charge density in the dielectrics was measured using SemiTest SCA-2500 surface charge analyzer, which allows contactless and non-destructive measurement of the flat band equivalent charge density (Q_{FB}, the total charge density at the flat band condition) in the dielectric of interest. The front and rear contacts were formed by screen-printing commercial Ag paste and Al paste, respectively, followed by firing in an IR metal belt furnace.

The hydrogen concentration in the SiCₓN_{Y} films was measured by Elastic Recoil Detection (ERD).

The efficiency of the solar cells was measured using a custom-made I-V system, with the solar cell illuminated at one sun conditions, 1,000 W/cm². The cell was kept at 25° C.

The equipment was calibrated with a solar cell obtained from the National Renewable Energy Laboratory of the US Department of Energy.

### Example 1

Boron doped Czochralski (Cz) silicon wafers of 1-3 ohm·cm base resistivity and 230 μm thickness were used as a substrate for 149 cm² screen printed solar cells. The results obtained with depositions made on a 45 Ω/sq emitter are shown in Table 1. For comparative purposes, SiNₓ layers were prepared from silane and NH₃. No optimizations were made for the SiCₓN_{y} depositions; the optimized process conditions for SiNₓ depositions were used. The dielectric layers prepared were fired at a temperature of 850° C. for 5 seconds following deposition.

TABLE 1
Electrical measurements on 45 Ω/sq emitters

| SiH₄ or | | | | | | | | |
|---|---|---|---|---|---|---|---|---|
| polymer | | | | | | | | |
| flow | NH3 | Voc | Jsc | Fill | Efficiency | n | Rseries | Rshunt |
| (sccm) | (sccm) | (mV) | (mA/cm²) | Factor | (%) | factor | (Ωcm²) | (Ωcm²) |
| 300 | 3000 | 623.0 | 34.92 | 0.783 | 17.0 | 1.07 | 0.781 | 4665 |
| (SiH4) | | | | | | | | |
| 300 | 3000 | 622.0 | 34.80 | 0.780 | 16.9 | 1.07 | 0.799 | 24922 |
| (polymer) | | | | | | | | |
| 300 | 4500 | 621.7 | 34.50 | 0.782 | 16.8 | 1.03 | 0.868 | 248209 |
| (polymer) | | | | | | | | |

### Example 2

In a manner similar to Example 1, solar cells were prepared with a 60 Ω/sq emitter, and results are shown in Table 2. Again, film thicknesses were not optimized for the SiNₓ film, and not the SiCₓN_{y} films.

TABLE 2
Electrical measurements on 60 Ω/sq emitters

| SiH₄ or | | | | | | | | |
|---|---|---|---|---|---|---|---|---|
| polymer | | | | | | | | |
| flow | NH3 | Voc | Jsc | Fill | Efficiency | n | Rseries | Rshunt |
| (sccm) | (sccm) | (mV) | (mA/cm²) | Factor | (%) | factor | (Ωcm²) | (Ωcm²) |
| 300 | 3000 | 620 | 36.1 | 0.763 | 17.1 | 1.07 | 1.077 | 2208 |
| (SiH₄) | | | | | | | | |
| 300 | 1500 | 618 | 35.6 | 0.772 | 17.0 | 1.02 | 1.043 | 40250 |
| (polymer) | | | | | | | | |
| 300 | 3000 | 618 | 35.8 | 0.766 | 17.0 | 1.06 | 1.044 | 24335 |
| (polymer) | | | | | | | | |
| 300 | 3000 | 619.7 | 35.90 | 75.6 | 16.82 | 1.08 | 1.101 | 2423 |
| (SiH₄) | | | | | | | | |
| 300 | 1500 | 616.9 | 35.51 | 76.9 | 16.84 | 1.05 | 1.05 | 28532 |
| (polymer) | | | | | | | | |
| 300 | 3000 | 616.7 | 35.71 | 76.7 | 16.89 | 1.06 | 1.04 | 58267 |
| (polymer) | | | | | | | | |

### Example 3

Further solar cells were prepared with 45 Ω/sq emitters, with an optimized SiCₓN_{y} film thickness for the obtained refractive index. Table 3 provides a comparison of the SiNₓ and SiCₓN_{y} films prepared.

TABLE 3
Optimized measurements on 45 Ω/sq emitters

| SiH₄ or | | | | | | | | |
|---|---|---|---|---|---|---|---|---|
| polymer | | | | | | | | |
| flow | NH3 | Voc | Jsc | Fill | Efficiency | n | Rseries | Rshunt |
| (sccm) | (sccm) | (mV) | (mA/cm²) | Factor | (%) | factor | (Ωcm²) | (Ωcm²) |
| 300 | 3000 | 620 | 34.99 | 0.772 | 16.76 | 1.14 | 0.791 | 2080 |
| (SiH4) | | | | | | | | |
| 300 | 3500 | 618 | 35.48 | 0.780 | 17.11 | 1.00 | 0.882 | 7541 |
| (polymer) | | | | | | | | |

### Example 4

Further solar cells were prepared with a Roth and Rau AK400 remote plasma tool, varying the carbon concentration in the deposited SiCₓN_{y} films. The efficiency of the prepared cells, as a function of the carbon content, is shown in FIG. 14.

### Composition of the SiCₓN_{y} Films

Auger analysis of the O, C, N and Si content of SiNₓ and SiCₓN_{y} dielectric films as described herein is provided in Table 4. These results are also displayed graphically in FIG. 1.

TABLE 4
Auger analsysis of SiNₓ and SiCₓN_{y} films

| | SiCN | | | | | |
|---|---|---|---|---|---|---|
| | NH₃ flow(sccm) | | | | | |
| | 1500 | 2000 | 2500 | 3000 | 4500 | SiN |
| O | 2.8 | 2.7 | 3.1 | 3.0 | 2.6 | 3.8 |
| (at. %) | | | | | | |
| C | 24.7 | 21.0 | 17.5 | 15.9 | 13.1 | 0.0 |
| (at. %) | | | | | | |
| N | 41.7 | 44.9 | 48.1 | 50.6 | 53.3 | 60.4 |
| (at. %) | | | | | | |
| S | 30.7 | 31.4 | 31.3 | 30.2 | 30.6 | 35.5 |
| (at. %) | | | | | | |

Hydrogen concentration analysis of SiNₓ and SiCₓN_{y} films, by Elastic Recoil Detection (ERD), is provided in FIG. 2. Hydrogen concentrations of SiNₓ and SiCₓN_{y} films are also provided in table 5:

TABLE 5
Hydrogen concentrations of SiNₓ and SiCₓN_{y} films

| | | SiCN | SiCN | SiCN | SiCN | SiCN |
|---|---|---|---|---|---|---|
| | | NH₃ @1500 | NH₃ @2000 | NH₃ @2500 | NH₃ @3000 | NH₃ @4500 |
| | SiN | sccm | sccm | sccm | sccm | sccm |
| H | 11.8 | 15.4 | 12.7 | 11.3 | 8.8 | 9.0 |
| (at. %) | | | | | | |

The combined Auger and ERD analysis are provided in Table 6.

TABLE 6
Chemical composition of SiNₓ and SiCₓN_{y} films

| | SiCN | | | | | |
|---|---|---|---|---|---|---|
| | NH₃ flow(sccm) | | | | | |
| | 1500 | 2000 | 2500 | 3000 | 4500 | SiN |
| H | 15.4 | 12.7 | 11.3 | 8.8 | 9.0 | 11.8 |
| (at. %) | | | | | | |
| O | 2.4 | 2.4 | 2.7 | 2.7 | 2.4 | 3.4 |
| (at. %) | | | | | | |
| C | 20.9 | 18.3 | 15.5 | 14.5 | 11.9 | 0.0 |
| (at. %) | | | | | | |
| N | 35.3 | 39.2 | 42.7 | 46.1 | 48.5 | 53.3 |
| (at. %) | | | | | | |
| S | 26.0 | 27.4 | 27.8 | 27.5 | 27.8 | 31.3 |
| (at. %) | | | | | | |

### Characterization of Optical Properties

The refractive index (n) and extinction coefficient (k) of SiNₓ and SiCₓN_{y} dielectric films as a function of NH₃ flow rate are summarized in Table 7. The n and k values were measured at the wavelengths of 630 nm and 300 nm, respectively.

TABLE 7
Refractive indices (n) and extinction coefficient (k) of SiNₓ and
SiCₓN_{y} films as a function of NH₃ flow rate.

| | Si | NH₃ | n | k |
|---|---|---|---|---|
| Film | Source | (sccm) | at 630 nm | at 300 nm |
| SiNₓ | SiH₄ | 3000 | 2.04 | 0.026 |
| SiCₓN_{y} | PDMS | 1500 | 1.97 | 0.052 |
| SiCₓN_{y} | PDMS | 2000 | 1.95 | 0.031 |
| SiCₓN_{y} | PDMS | 2500 | 1.94 | 0.027 |

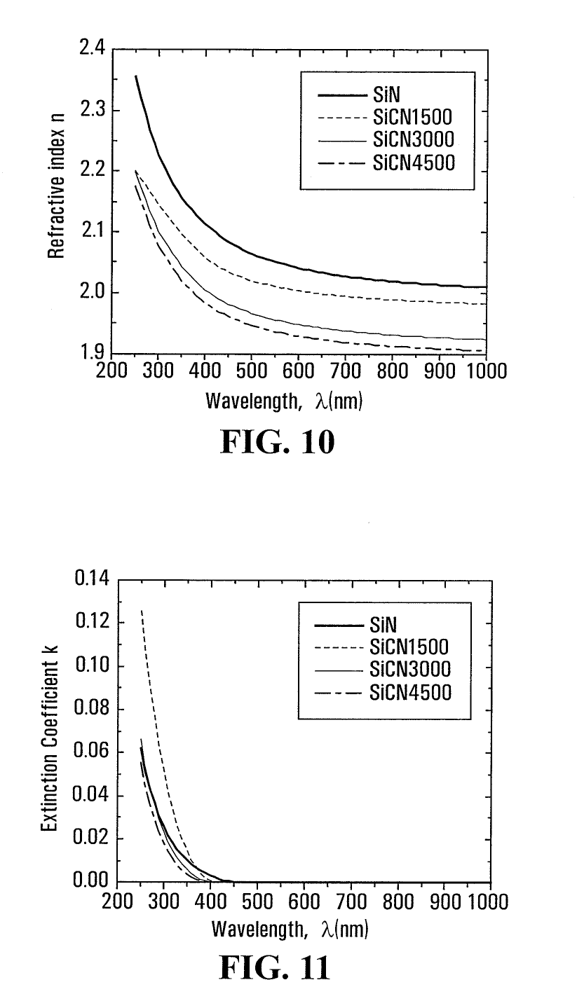

Graphical representation of the refractive index and extinction coefficient of SiNₓ and SiCₓN_{y} dielectric layers, obtained by spectroscopic ellipsometry (VASE), are provided in FIGS. 10 and 11.

In a separate experiment, it was found that the refractive index can be increased up to ˜(2.3) as the NH₃ flow rate is decreased during the production of SiCₓN_{y}. The base process without NH₃ flow was nominally stoichiometric SIC since there is no nitrogen source. However, since the screen printed contact formation process used was optimized for conventional SiNₓ films, NH₃ flow rates in the range of 1500-2500 sccm were used as these yield similar Si/N compositions to that of the SiNₓ film. By adjusting the source composition and gas flow rates, SiCₓN_{y} films with a refractive index range of 1.94-1.97 at 630 nm wavelength were obtained.

### Characterization of Electrical Properties

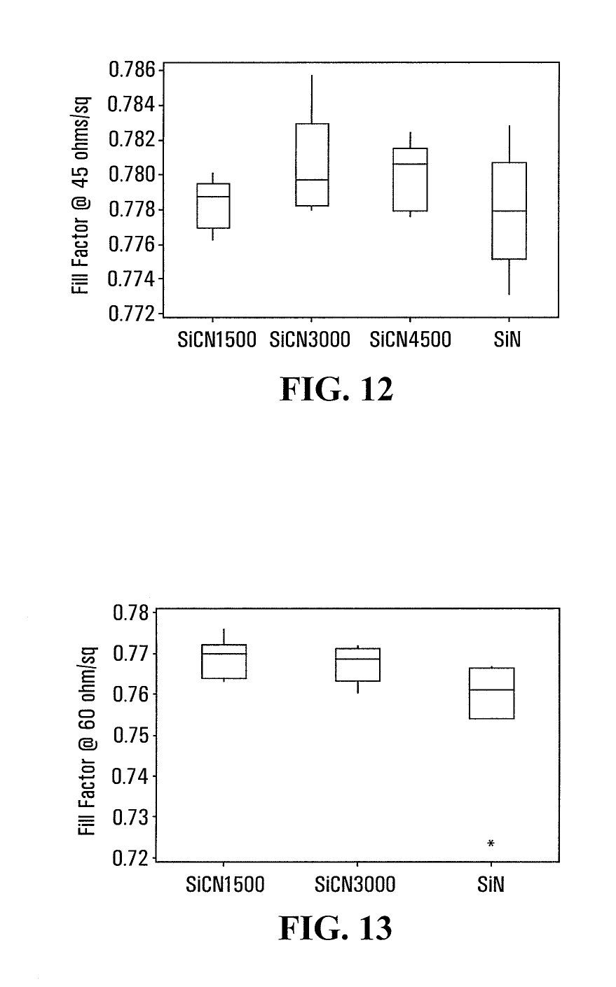

Boxplot graphs of Fill Factor values measured for SiCₓN_{y} and SiNₓ solar cells prepared on 45 and 60 ohm/sq emitters are provided in FIGS. 12 and 13. Fill Factor enhancements are observed both in terms of percentage increases and narrowing of distribution for the SiCₓN_{y} antireflective coatings over the SiNₓ films, indicating improvements in contact properties. J_{oE} values were measured for SiNₓ and SiCₓN_{y} solar cells prepared on 45 ohm/sq textured emitters and the results are presented in FIG. 4. All the samples were fired in an RTP chamber at 850° C. for 5 sec before J_{oE} measurement. A boxplot of J_{oE} values for pre- and post-fired SiNₓ and SiCₓN_{y} films is also provided in FIG. 5.

FIG. 6 shows the surface charge densities (Q_{FB}) in SiNₓ and SiCₓN_{y} dielectric films after annealing in an RTP chamber at 850° C. for 5 sec. The surface charge density in the SiCₓN_{y} film was measured to be in the range of 1.58−1.77×10¹²/cm² which is slightly lower than that of SiNₓ film (1.89×10¹²/cm²).

Internal quantum efficiency (IQE) and reflectance values measured on the two types of cells were measured and are presented in FIG. 8. A boxplot of lifetime measurements for pre- and post-fired SiNₓ and SiCₓN_{y} films is provided in FIG. 7.

### Example 5

SiCₓN_{y} films were deposited by PECVD using as gaseous precursors NH₃ and methylsilane, dimethylsilane, trimethylsilane, tetramethylsilane, or a mixture (identified as SiXG3.1) comprising about 3 vol. % monomethylsilane, about 36 vol. % dimethylsilane, about 2 vol. % trimethyl silane, about 12 vol. % methane, and hydrogen.

A SEMCO™ low frequency direct plasma PECVD system was used for the deposition. The pressure in the chamber was kept at 1.8 Torr during the deposition processes, the deposition temperature was 500° C., and the peak power was 3.6 kW. The flow rates for the organosilane (or mixture) were varied from 5 to 108 sccm, the flow rate for NH₃ was varied from 250 to 4900 sccm, and gas flow rate ratios between the organosilane (or mixture) and NH₃ were varied from 3.5 to 257. The films were deposited on n-type c-Si (100) substrates with resistivity of 1-10 Ohmcm and on mono and multi-crystalline silicon solar cells.

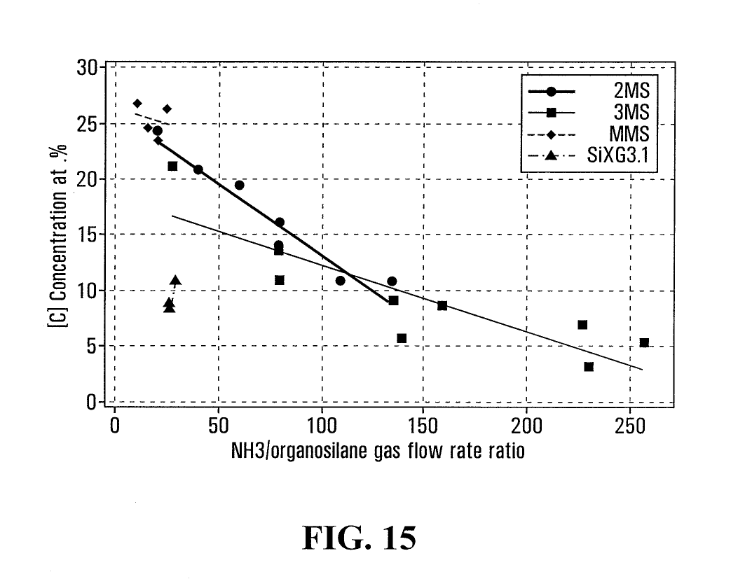

The composition of the obtained films was characterized by Auger spectroscopy. The carbon concentrations (in atomic percent) of select films are plotted in FIG. 15, where 2MS represents films prepared from a combination of NH₃ and dimethylsilane, 3MS represents films prepared from a combination of NH₃ and trimethylsilane, MMS represents films prepared from a combination of NH₃ and methylsilane, and SiXG3.1 represents films prepared from a combination of NH₃ and the gaseous mixture as defined above.

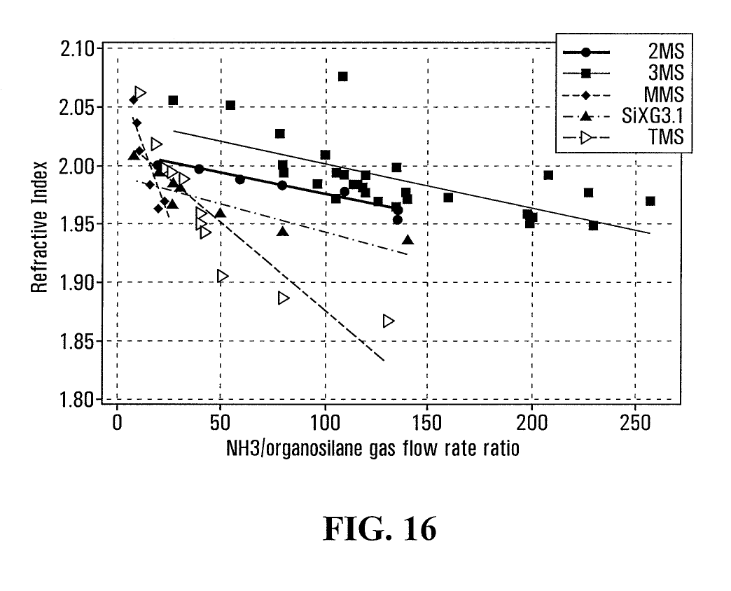

Spectroscopic ellipsometry was used to evaluate the refractive index (n) of the resulting films, and these results are shown in FIG. 16. In the figure, 2MS, 3MS, MMS and SiXG3.1 have the same meanings as given above, and TMS represents films prepared from a combination of NH₃ and tetramethylsilane.

All publications, patents and patent applications cited in this specification are herein incorporated by reference as if each individual publication, patent or patent application were specifically and individually indicated to be incorporated by reference. The citation of any publication is for its disclosure prior to the filing date and should not be construed as an admission that the present invention is not entitled to antedate such publication by virtue of prior invention.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

It must be noted that as used in this specification and the appended claims, the singular forms “a”, “an”, and “the” include plural reference unless the context clearly dictates otherwise. Unless defined otherwise all technical and scientific terms used herein have the same meaning as commonly understood to one of ordinary skill in the art to which this invention belongs.

### REFERENCES

1. R. Hezel and R. Schorner, “Plasma Si nitride-a promising dielectric to achieve high-quality silicon MIS/IL solar cells”, J. Appl. Phys., vol. 52, p. 3076, 1981
2. J. Schmidt, T. Lauinger, A. G. Aberle, and R. Hezel, “Record low surface recombination velocities on low resistivity silicon solar cell substrate”, 25^{th} IEEE PVSC, Washington, D.C., p. 413, 1996.
3. S. W. Glunz, S. Janz, M. Hofmann, T. Roth, and G. Willeke, “Surface passivation of silicon solar cells using amorphous silicon carbide layers”, 4^{th} WCPEC, Waikola, p. 4, 2006.
4. I. Martin, M. Vetter, A. Orpella, and J. Puigdollers, A. Cuevas and R. Alcubilla, “Surface passivation of p-type crystalline Si by plasma enhanced chemical vapor deposited amorphous SiCx:H films”, App. Phys. Lett, vol. 79, no. 14, p. 2199, 2001.
5. V. Meemongkolkiat, D. S. Kim, and A. Rohatgi, “SiO₂-based spin-on dielectrics for back surface passivation of p-type Si solar cells”, 22^{nd} European PVSEC, Italy, 2007.
6. S. D. Wolf, G. Agostinelli, G. Beaucarne and P. Vitanov, “Influence of stoichiometry of direct plasma-enhanced chemical vapor deposited SiNₓ films and silicon substrate surface roughness on surface passivation”, J. Appl. Phys., vol. 97, p. 63303, 2005.
7. Vetter et al. “IR-study of a-SiCₓ:H and a-SiCₓN_{y}:H films for c-Si surface passivation”, Thin Solid Films 451-452 (2004) 340-344.
8. Glunz et al. “Comparison of Different Dielectric Passivation in Industrially Feasible High-Efficiency Crystalline Silicon Solar Cells”, Presented at the 20^{th} European Photovoltaic Solar Energy Conference and Exhibition, 6-10 Jun. 2005, Barcelona.
9. Limmanee et al. “Effect of thermal annealing on the properties of a-SiCN:H films by hot wire chemical vapour deposition using hexmethyldisilazane”, Thin Solid Films 516 (2008) 652-655.
10. Limmanee et al. “Effect of nitrogen addition on the properties of a-SiCN:H films using hexmethyldisilazane”, Mater. Res. Soc. Symp. Proc. Vol. 989 (2007).
11. Limmannee et al. “Study of the structural properties of a-SiCN:H films using hexamethyldisilazane for high-quality silicon passivation”, Proceeding of IEEE 4^{th} World Conference on Photovoltaic Energy Conversion, Hawai, U.S.A, May 7-12, 2006.
12. M. Zeman, J. Krc “Optical and electrical modeling of thin-film silicon solar cells”, Journal of Materials Research Volume: 23 No 4 Pages: 889-898.
13. D. E. Carlson, K. Rajan, R. R. Arya, F. Willing, L. Yang “Advances in amorphous silicon photovoltaic technology”, Journal of Materials Research Volume: 13 No 10 Pages: 2754-2762.
14. J. Yang, A. Banerjee, and S. Guha “Triple-junction amorphous silicon alloy solar cell with 14.6% initial and 13.0% stable conversion efficiencies”, Appl. Phys. Lett. 70, 2975 (1997).
15. K. Nakayashiki, B. Rounsaville, V. Yelundur, D. S. Kim, A. Rohatgi, R. Clark-Phelps, and J. I. Hanoka “Fabrication and analysis of high-efficiency String Ribbon Si solar cells”, Solid-State Electron. 50, 1406 (2006).
16. Mark Kerr, Jan Schmidt, Andres Cuevas “Comparison of the open circuit voltage of simplified PERC cells passivated with PECVD silicon nitride and thermal silicon oxide”, Progress in Photovoltaics: Research and Applications Volume 8 Issue 5, Pages 529-536.
17. J. Zhao, A Wang, P Campbell, M. A. Green “22.7% efficient PERL silicon solar cell module with a textured front surface”, Photovoltaic Specialists Conference, 1997., Conference Record of the Twenty-Sixth IEEE 29 Sep.-3 Oct. 1997 Pages 1133-1136.

1. A process for forming an antireflective coating on a silicon solar cell, comprising depositing by plasma-enhanced chemical vapour deposition (PECVD), on a silicon p-n junction, a gaseous mixture comprising a) one or more gaseous mono-silicon organosilane and b) a nitrogen-containing gas.

2. The process according to claim 1, wherein the one or more gaseous mono-silicon organosilane is methylsilane.

3. The process according to claim 1, wherein the one or more gaseous mono-silicon organosilane is dimethylsilane.

4. The process according to claim 1, wherein the one or more gaseous mono-silicon organosilane is trimethylsilane.

5. The process according to claim 1, wherein the one or more gaseous mono-silicon organosilane is tetramethyl silane.

6. The process according to claim 1, wherein the one or more gaseous mono-silicon organosilane comprises a mixture of two or more of methylsilane, dimethylsilane, trimethylsilane and tetramethylsilane.

7. The process according to claim 6, wherein the one or more gaseous mono-silicon organosilane is obtained from pyrolysis of a solid organosilane source.

8. The process according to claim 7, wherein the solid organosilane source is polydimethylsilane, polycarbomethylsilane, triphenylsilane, or nonamethyltrisilazane.

9. The process according to claim 1, wherein the gaseous mixture is formed by combining (a) the one or more gaseous mono-silicon organosilanes and (b) the nitrogen-containing gas in a flow ratio (a:b) of from 1:3.5 to 1:257; from 1:5 to 1:15; or from 1:6.6 to 1:15.

10. The process according to claim 1, further comprising the step of combining the gaseous mixture with a reactant gas, such as O₂, O₃, CO, CO₂ or a combination thereof, prior to the deposition.

11. The process according to claim 1, wherein the plasma enhanced chemical vapour deposition is radio frequency plasma enhanced chemical vapour deposition (RF-PECVD), electron-cyclotron-resonance plasma-enhanced chemical-vapour deposition (ECR-PECVD), inductively coupled plasma-enhanced chemical-vapour deposition (ICP-ECVD), plasma beam source plasma enhanced chemical vapour deposition (PBS-PECVD), or a combination thereof.

12. The process according to claim 1, wherein the antireflective coating comprises amorphous silicon carbonitride with an amount of carbon of from about 5 to about 25 atomic %; from about 5 to about 19 atomic %; from about 5 to about 15 atomic %; from about 10 to about 19 atomic %; or from about 14 to about 18 atomic %.

13. The process according to claim 1, wherein the solar cell has a Fill Factor greater than 75%.

14. The process according to claim 1, wherein the solar cell has a Fill Factor greater than 70% after being fired at a temperature of 800° C. or greater.

15. The process according to claim 1, wherein the antireflective coating is deposited on the front side of a substrate comprising the p-n junction, the backside of the substrate, or both.

16. A silicon solar cell prepared according to the process of claim 2, 3, 4, 5 or 6.
